(19) United States
(12) Patent Application Publication
(10) Pub. No.: US 2016/0284543 A1
(43) Pub. Date: Sep. 29, 2016

(54) SUBSTRATE PROCESSING APPARATUS, PROGRAM AND METHOD OF MANUFACTURING SEMICONDUCTOR DEVICE

(71) Applicant: HITACHI KOKUSAI ELECTRIC INC., Tokyo (JP)

(72) Inventors: Kazuyuki TOYODA, Toyama-shi (JP); Akihiro SATO, Toyama-shi (JP); Yukitomo HIROCHI, Toyama-shi (JP)

(73) Assignee: HITACHI KOKUSAI ELECTRIC INC., Tokyo (JP)

(21) Appl. No.: 15/078,503

(22) Filed: Mar. 23, 2016

(30) Foreign Application Priority Data
Mar. 27, 2015 (JP) 2015-066327

(51) Int. Cl. H01L 21/02; H01J 37/32; H01L 21/673

(52) U.S. Cl. CPC H01L 21/02274; H01L 21/02164; H01L 21/67313; H01J 37/3244; H01J 37/32568; H01J 37/32715; H01J 2237/332

(57) ABSTRACT

A substrate processing apparatus includes: a substrate holder configured to hold a substrate; a gas supply unit configured to supply gas of processing the substrate; a plasma electrode device provided separately above a surface of the substrate, configured to generate plasma of activating the gas supplied from the gas supply unit; and a rotation driving unit connected to the plasma electrode device, configured to horizontally move the plasma electrode device above the substrate.

### BACKGROUND

1. Technical Field

The present teachings relate to a substrate processing apparatus configured to process a substrate by using plasma, and a program and method of manufacturing a semiconductor device.

2. Related Art

As one manufacturing process of a semiconductor device, substrate processing may be performed for forming a film on a substrate by supplying a source and a reactant to the substrate in a processing chamber.

### SUMMARY

An objective of the present teachings is to provide a technique capable of improving film quality of a film to be formed.

According to an aspect of the present teachings,

a technique including:

a substrate holder configured to hold a substrate;

a gas supply unit configured to supply gas of processing the substrate;

a plasma electrode device provided separately above a surface of the substrate, configured to generate plasma of activating the gas supplied from the gas supply unit; and

a rotation driving unit connected to the plasma electrode device, configured to horizontally move the plasma electrode device above the substrate is provided.

According to the present teachings, it becomes possible to provide the technique capable of improving the film quality of the film to be formed.

### BRIEF DESCRIPTION OF DRAWINGS

FIG. 1 is a schematic configuration diagram of a vertical type substrate processing apparatus of a substrate processing apparatus suitably used in a first embodiment of the present teachings;

FIG. 2 is a diagram illustrating by a longitudinal cross-sectional view of a processing furnace part of the substrate processing apparatus suitably used in the first embodiment of the present teachings;

FIG. 3 is a schematic configuration diagram of the substrate processing apparatus suitably used in the first embodiment of the present teachings, and is a diagram enlarging the processing furnace part illustrated with a broken line part of FIG. 2;

FIG. 4 is a schematic configuration diagram of the substrate processing apparatus suitably used in the first embodiment of the present teachings, and is a diagram illustrating the processing furnace part with an A-A line cross-sectional view of FIG. 2;

FIG. 5 is a diagram illustrating a mounting state of a plasma electrode support and an electrode suitably used in the present teachings;

FIG. 6 is a flowchart for describing a process in substrate processing of the present teachings;

FIG. 7 is a time chart for describing the process in the substrate processing of the present teachings;

FIG. 8A is a diagram illustrating a movement locus of a plasma electrode of a substrate processing apparatus suitably used in the first embodiment of the present teachings;

FIG. 8B is a diagram illustrating a movement locus of a plasma electrode of a substrate processing apparatus suitably used in a second embodiment of the present teachings;

FIG. 9 is a schematic configuration diagram of a controller of the substrate processing apparatus suitably used in the first embodiment of the present teachings, and is a block diagram illustrating a control system of the controller;

FIG. 10 is a diagram illustrating a chemical structural formula of BTBAS;

FIG. 11 is a diagram illustrating an electrode stop position at the time of supplying source gas in the present teachings;

FIG. 12 is a diagram illustrating a rotation range of a boat at the time of supplying the source gas in the present teachings; and

FIG. 13 is a diagram illustrating a first modified example of timing of supplying RF power in the first embodiment of the present teachings.

### DETAILED DESCRIPTION

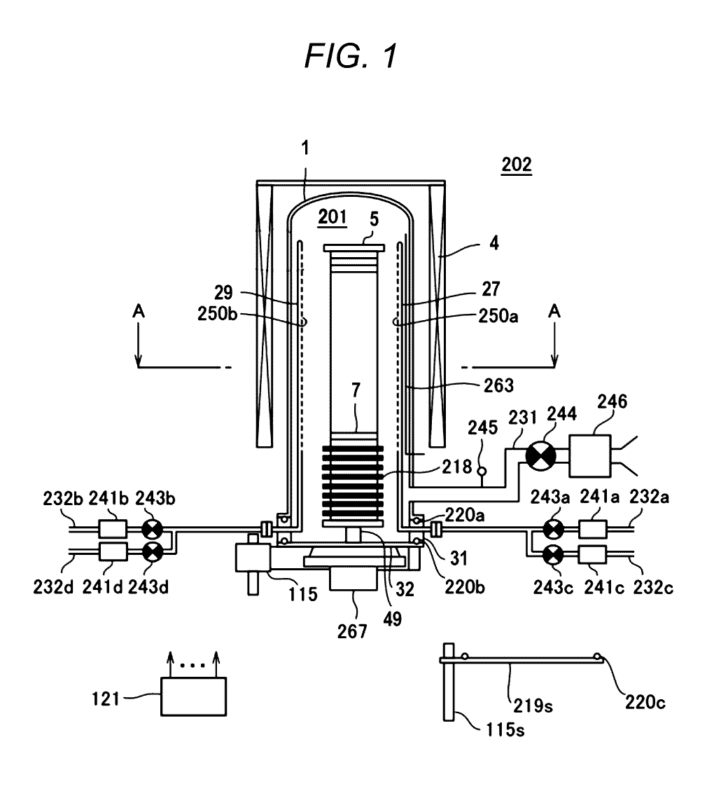

Hereinafter, a first embodiment of the present teachings is described with reference to FIG. 1. Incidentally, in the figure, to facilitate the description, a plasma generator, a plasma electrode, and the like are omitted.

### (1) Configuration of Substrate Processing Apparatus

(Heating Apparatus)

As illustrated in FIG. 1, a processing furnace 202 includes a heater 4 as a heating apparatus (heating mechanism). The heater 4 has a cylindrical shape, and is vertically installed by being supported by a heater base as a holding plate (not illustrated). The heater 4, as described later, also functions as an activation mechanism (excitation unit) configured to activate (excite) gas by heat.

(Processing Chamber)

Inside the heater 4, a reaction tube 1 is disposed concentrically with the heater 4. The reaction tube 1 is made of heat-resistant material, for example, quartz (SiO₂) or silicon carbide (SiC), and is formed in a cylindrical shape of which upper end is closed and lower end is opened. On the lower side of the reaction tube 1, a manifold 31 is disposed concentrically with the reaction tube 1. The manifold 31 is made of metal, for example, stainless steel (SUS), and is formed in a cylindrical shape of which upper end and lower end are opened. The upper end part of the manifold 31 is engaged with the lower end part of the reaction tube 1 and configured to support the reaction tube 1. Between the manifold 31 and the reaction tube 1, an O ring 220a is provided as a seal member. The manifold 31 is supported by a heater base, so that the reaction tube 1 is in a state of being installed vertically. A processing container (reaction container) is configured mainly by the reaction tube 1 and the manifold 31. In a cylindrical hollow part of the processing container, a processing chamber 201 is formed. The processing chamber 201 is configured to be capable of accommodating wafers 7 as a plurality of substrates in a state of being arranged in multiple stages in the vertical direction in the horizontal posture by a boat 5 as a substrate holder described later.

(Gas Supply Unit)

In the processing chamber 201, nozzles 27, 29 are provided to penetrate the side wall of the manifold 31. Gas supply pipes 232a, 232b are respectively connected to the nozzles 27, 29. In this way, two nozzles 27, 29 and two gas supply pipes 232a, 232b are provided to the reaction tube 1, and a plurality of types of gas can be supplied into the processing chamber 201.

Mass flow controllers (MFCs) 241a, 241b being flow rate controllers (flow rate control units), and valves 243a, 243b being on-off valves are respectively provided, in order from the upstream direction, to the gas supply pipes 232a, 232b. Gas supply pipes 232c, 232d for supplying inert gas are respectively connected to the downstream sides from the valves 243a, 243b of the gas supply pipes 232a, 232b. MFCs 241c, 241d being flow rate controllers (flow rate control units), and valves 243c, 243d being on-off valves are respectively provided, in order from the upstream direction, to the gas supply pipes 232c, 232d.

The nozzles 27, 29 are respectively connected to the tip parts of the gas supply pipes 232a, 232b. The nozzles 27, 29 are each provided to stand up toward a loading direction of the wafers 7, along from the lower part to the upper part of the inner wall of the reaction tube 1, in an annular space in the plan view between the inner wall of the reaction tube 1 and the wafers 7. That is, the nozzles 27, 29 are each provided along a wafer arrangement region, in a region surrounding the wafer arrangement region horizontally (annularly), of the side of the wafer arrangement region in which the wafers 7 are arranged. That is, the nozzles 27, 29 are each provided vertically to surfaces (flat surfaces) of the wafers 7, at the side of the end part (peripheral part) of each of the wafers 7 loaded into the processing chamber 201. The nozzles 27, 29 are each configured as an L-shaped long nozzle, and the horizontal parts are provided to penetrate the side wall of the manifold 31, and the vertical parts are provided to stand up at least from one end side toward the other side of the wafer arrangement region. Gas supply holes 250a, 250b for supplying gas are respectively provided to the side surfaces of the nozzles 27, 29. The gas supply holes 250a, 250b each open to face the center of the reaction tube 1 (wafers 7), and the gas can be supplied to the wafers 7. The gas supply holes 250a, 250b each include a plurality of holes across from the lower side to the upper side of the reaction tube 1, and each have the same opening area, and further, are provided at the same opening pitch. Incidentally, the opening area of the gas supply holes 250a, 250b can be increased gradually toward the downstream side from the upstream side, and the opening pitch of the gas supply holes 250a, 250b can be decreased gradually toward the downstream side from the upstream side.

In this way, in the present embodiment, the gas is carried via the nozzles 27, 29 disposed in the annular longitudinal space in the plan view, that is, a cylindrical space, which is defined by the inner wall of the side wall of the reaction tube 1 and the end part (peripheral part) of the wafers 7 arranged in the reaction tube 1. The gas is jetted into the reaction tube 1 for the first time near the wafers 7 from the gas supply holes 250a, 250b respectively opened in the nozzles 27, 29. A main flow of the gas in the reaction tube 1 is made to be in a direction parallel to the surfaces of the wafers 7, that is, the horizontal direction. By such a configuration, it becomes possible to supply the gas uniformly to each of the wafers 7, and to improve uniformity of film thickness of a film formed on each of the wafers 7. The gas flowing on the surfaces of the wafers 7, that is, residual gas after reaction, flows toward a direction of an exhaust port, that is, an exhaust pipe 231 described later. However, the direction of the flow of the residual gas is appropriately specified depending on the position of the exhaust port, and is not limited to the vertical direction.

From the gas supply pipe 232a, as a source containing a predetermined element, for example, silane source gas containing silicon (Si) as the predetermined element is supplied into the processing chamber 201 via the MFC 241a, valve 243a, and nozzle 27.

The silane source gas is a silane source in the gas state, for example, gas obtained by vaporizing a silane source being in the liquid state under normal temperature and normal pressure, and a silane source being in the gas state under normal temperature and normal pressure. When using the term “source” in the present specification, it may mean “liquid source in the liquid state,” “source gas in the gas state,” or both.

As the silane source gas, for example, source gas containing Si and an amino group (amine group), that is, aminosilane source gas can be used. The aminosilane source is a silane source including the amino group, and also is a silane source including an alkyl group such as a methyl group, ethyl group, and butyl group, and is a source containing at least Si, nitrogen (N), and carbon (C). That is, the aminosilane source referred to here can also be referred to as an organic-based source, and can also be referred to as an organic aminosilane source.

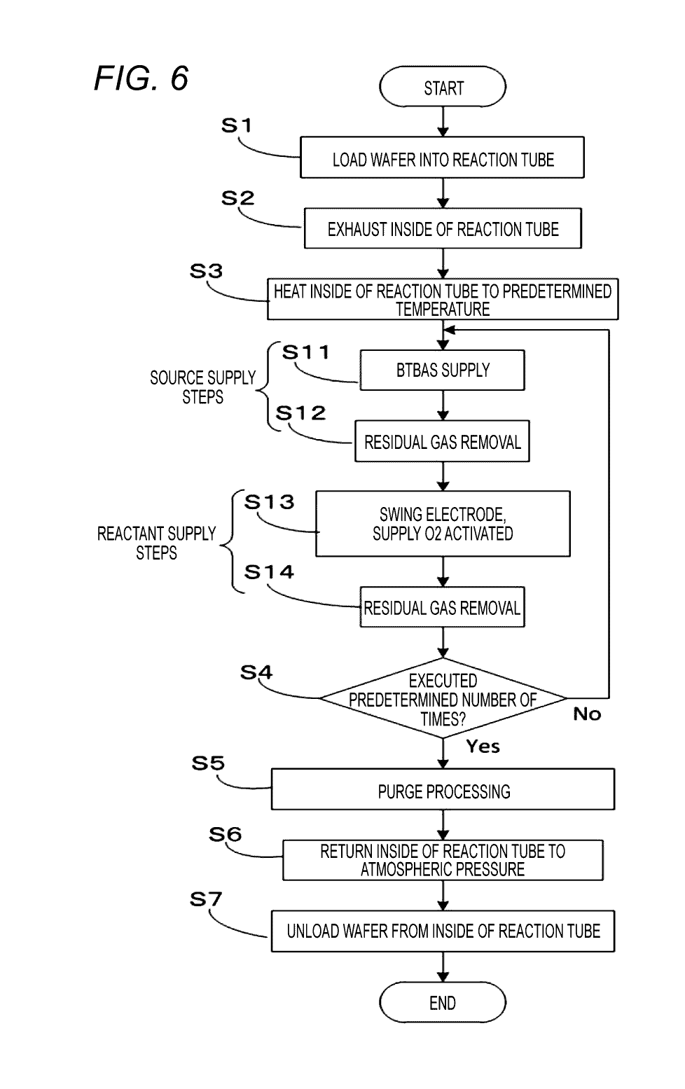

As the aminosilane source gas, for example, bis-tertiary butyl amino silane (SiH₂[NH(C₄H₉)]₂, abbreviation: BTBAS) gas can be used. A chemical structural formula of BTBAS is illustrated in FIG. 6. BTBAS contains one element of Si in one molecule, and has a Si—N bond, a N—C bond, and can be referred to as source gas not having a Si—C bond. BTBAS gas acts as Si source in film-forming processing described later.

When using a liquid source in the liquid state under normal temperature and normal pressure, such as BTBAS, the source in the liquid state is vaporized by a vaporization system such as a vaporizer and a bubbler, and supplied as the silane source gas (such as the BTBAS gas).

From the gas supply pipe 232b, as a reactant having different chemical structure from the source, for example, oxygen (O)-containing gas is supplied into the processing chamber 201 via the MFC 241b, valve 243b, and nozzle 29.

The O-containing gas, in the film-forming processing described later, acts as an oxidant (oxidation gas), that is, an O source. As the O-containing gas, for example, oxygen (O₂) gas and water vapor (H₂O gas) can be used. When using the O₂ gas as the oxidant, for example, plasma is excited in the gas by using a plasma source described later, and the gas is supplied as plasma excitation gas (O₂* gas).

From the gas supply pipes 232c, 232d, as the inert gas, for example, nitrogen (N₂) gas is supplied into the processing chamber 201 via MFCs 241c, 241d, valves 243c, 243d, gas supply pipes 232a, 232b, and nozzles 27, 29 respectively.

In the film-forming processing described later, when supplying the above-described source from the gas supply pipe 232a, a source supply system as a first supply system is configured mainly by the gas supply pipe 232a, MFC 241a, and valve 243a. The nozzle 27 can be considered to be included in the source supply system. When supplying the aminosilane source from the gas supply pipe 232a, the source supply system can be referred to as an aminosilane source supply system, or an aminosilane source gas supply system.

In addition, in the film-forming processing described later, when supplying the above-described reactant from the gas supply pipe 232b, a reactant supply system as a second supply system is configured mainly by the gas supply pipe 232b, MFC 241b, and valve 243b. The nozzle 29 can be considered to be included in the reactant supply system. When supplying the oxidant from the gas supply pipe 232b, the reactant supply system can be referred to as an oxidant supply system, an oxidation gas supply system, or an O-containing gas supply system.

In addition, in purge processing described later, an inert gas supply system is configured mainly by the gas supply pipes 232c, 232d, MFCs 241c, 241d, and valves 243c, 243d.

(Substrate Support)

As illustrated in FIG. 1, the boat 5 as a substrate support is configured to support the multiple, for example 25-200, wafers 7 in multiple stages by vertically aligning in the horizontal posture and in a state in which each center is aligned, that is, to align at intervals. The boat 5 is made of heat-resistant material such as quartz and SiC. In the lower part of the boat 5, a heat insulation plate 218 made of the heat-resistant material such as quartz and SiC is supported in multiple stages. With this configuration, heat from the heater 4 is not easily transmitted to the seal cap 32 side. However, the present embodiment is not limited to such a form. For example, without providing the heat insulation plate 218 to the lower part of the boat 5, a heat insulation cylinder can be provided that is configured as a cylindrical member made of the heat-resistant material such as quartz and SiC.

(Rotation Driving Unit and Plasma Electrode Mechanism)

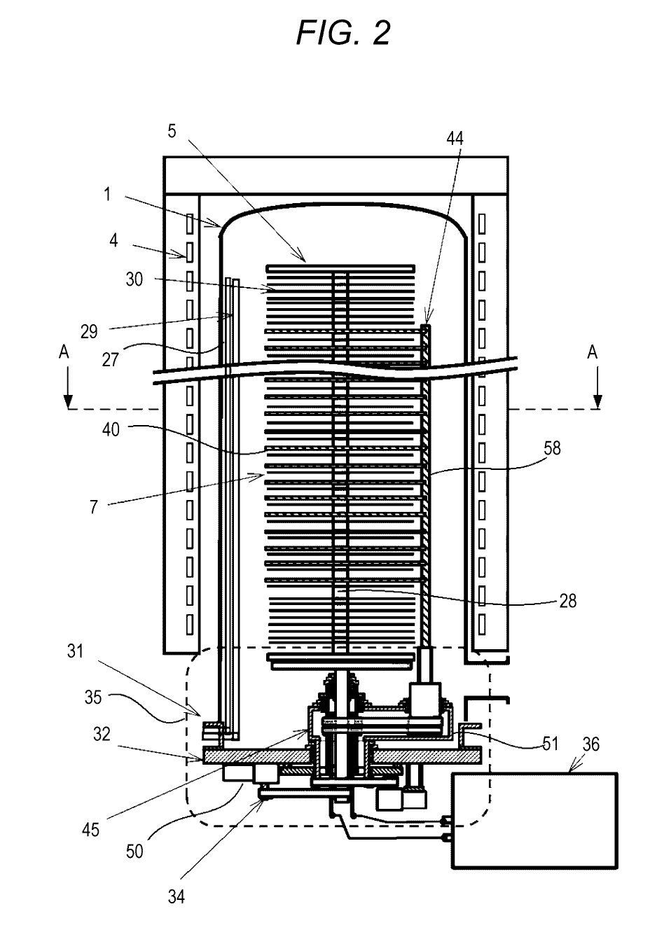

A rotation driving unit and plasma electrode mechanism is described that is a feature point of the present teachings with reference to FIGS. 2, 3, 4, and 5.

A quartz reaction tube 1 has structure in which the upper part is closed and the lower part is opened, and the manifold 31 is provided, and further, the opening side of the manifold 31 has structure opened and closed by the seal cap 32. The reaction tube 1 has structure in which the opening end and the manifold 31 are sealed by an O ring, and, when the opening end of the manifold 31 is closed by the seal cap 32, air tightness is held by the O ring.

As illustrated in FIG. 2, a rotation driving unit 35 described later is disposed below the boat 5, and is able to drive an electrode swing arm 45 as an electrode driving arm to move an electrode support 44 described later rotatably attached to the tip part of the electrode swing arm 45, in an arc shape near the periphery of the boat 5 (or wafers 7).

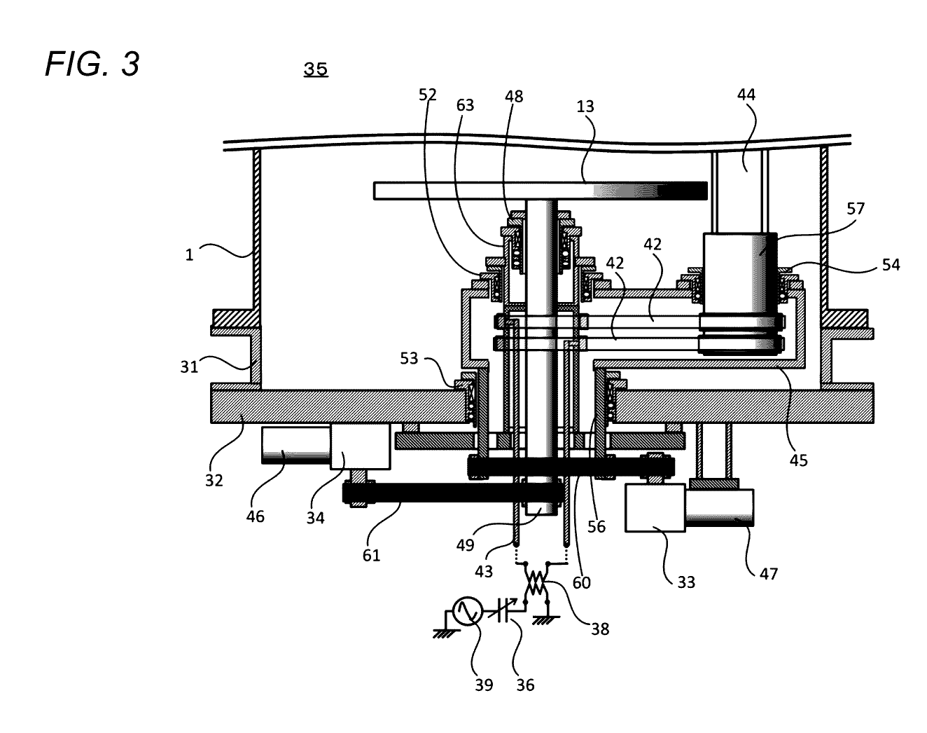

As illustrated in FIG. 3, the rotation driving unit 35 is configured by a boat driving system 50 for rotating the boat 5, and a plasma electrode driving system 51 for rotating the electrode swing arm 45 and the electrode support 44.

The boat driving system 50 is configured by at least a rotation shaft 49 as a boat rotation shaft for rotating a boat table 13, and a boat rotation motor 46 as a boat driving source for rotating the rotation shaft 49, and, if needed, there is provided a gear head 34 and a driving belt 61 for transmitting driving force of the boat rotation motor 46 to the rotation shaft 49. To the rotation shaft 49, a boat table base shaft 63 is provided to be coaxial, and due to the fact that a magnetic seal 48 is provided between the boat table base shaft and the rotation shaft, it becomes possible to rotate the rotation shaft 49 and to hold air tightness. Further, the boat table base shaft 63 is attached to the electrode swing arm 45 to be coaxial by a magnetic seal 52. Thus, the electrode swing arm 45 is configured to be able to rotate while keeping air tightness. With this configuration, the electrode swing arm 45 and the boat table 13 are independently rotatable.

The plasma electrode driving system 51 is configured by at least an electrode swing arm shaft 56 coupled to the electrode swing arm 45 as a first electrode driving shaft for rotating the electrode swing arm 45, an electrode swing motor 47 as the electrode driving source for rotating the electrode swing arm shaft 56, and an electrode support base shaft 57 provided to the electrode swing arm 45 and coupled to the electrode support 44, and, if needed, there is provided a gear head 33 and a driving belt 60 for transmitting driving force of the electrode swing motor 47 to the electrode swing arm shaft 56, and a conductive RF feeder belt 42 bridgingly provided between the above-described boat table base shaft 63 and the electrode support base. The electrode swing arm shaft 56 coupled to the electrode swing arm 45 is attached to the seal cap 32, in a state of being rotatable and keeping air tightness, by a magnetic seal 53. In addition, the electrode support base shaft 57 as a second electrode driving shaft coupled to the electrode support 44 is attached to the electrode swing arm 45, in a state of being rotatable and keeping air tightness, by a magnetic seal 54.

As illustrated in FIG. 2 and FIG. 3, a plasma electrode mechanism (plasma electrode structure) 58 provided to face the gas supply nozzles 27, 29 sandwiching the boat is configured by at least an electrode 40, an insulation plate 55, the electrode support 44, and the electrode swing arm 45, and, if needed, the electrode support base shaft 57 and the above-described plasma electrode driving system 51 can be considered to be included in the plasma electrode mechanism 58. When the plasma electrode driving system 51 is included in the plasma electrode mechanism, the rotation driving unit 35 is configured by the boat driving system 50. Incidentally, the insulation plate 55 and the electrode support 44 can be considered to be included in the electrode 40.

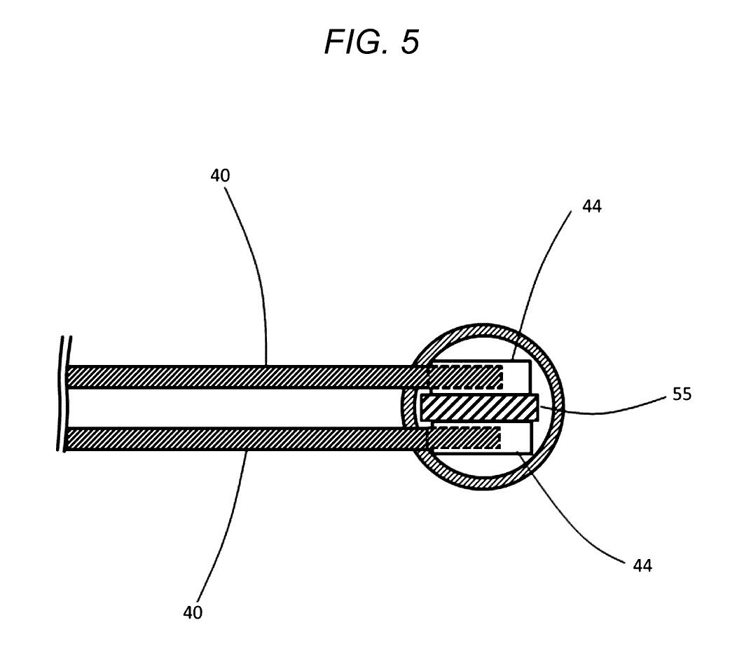

As illustrated in FIG. 2 and FIG. 3, to the electrode swing arm shaft 56, the electrode support 44 is vertically provided to be coaxial. To the side surface of the electrode support 44, as illustrated in FIG. 5, a pair of electrodes 40 is provided to sandwich the insulation plate 55, and the electrodes 40 are provided to be positioned above the wafers 7 being processing targets. Here, the electrodes 40, as illustrated in FIG. 2, can be configured to be provided horizontally at equal intervals on the side surface of the electrode support 44 to be positioned above the wafers 7 loaded in multiple stages, and, in a case of a substrate processing apparatus in which the wafer 7 being the processing target is only one, the electrode 40 can be configured to be provided only one.

The plasma electrode mechanism has structure in which: an RF feeder 43 connected to an oscillator 39 via an isolation transformer 38, a matching device 36 is connected to each of a pair of the RF feeder belts 42; high frequency power generated by the oscillator 39 is applied to the electrode 40 via the matching device 36, the isolation transformer 38, the RF feeder 43, the RF feeder belt 42, the electrode support 44; and plasma 41 is generated along the electrode 40.

Here, for material of the RF feeder belt 42, to transmit high frequency power supplied from the oscillator 39 as a high frequency power source, conductive material is utilized, such as metal material such as stainless steel (SUS). In addition, as material of the electrode 40 and the electrode support 44, aluminum (Al), stainless steel, carbon, silicon carbide (SiC), Si can be used. When, for example, Si is used as the material of the electrode 40 and the electrode support 44, high purity Si is desirable, in which foreign matter control is easy. In addition, as material of the insulation plate 55 sandwiched by the electrodes 40, high purity quartz (SiO₂), ceramics (high purity alumina (Al₂O₃)), and the like can be used, and when used in the substrate processing apparatus as the present embodiment, high purity quartz is desirable, in which foreign matter control is easy. As material of the electrode support base shaft 57, high purity quartz, ceramics (high purity alumina), and the like are used.

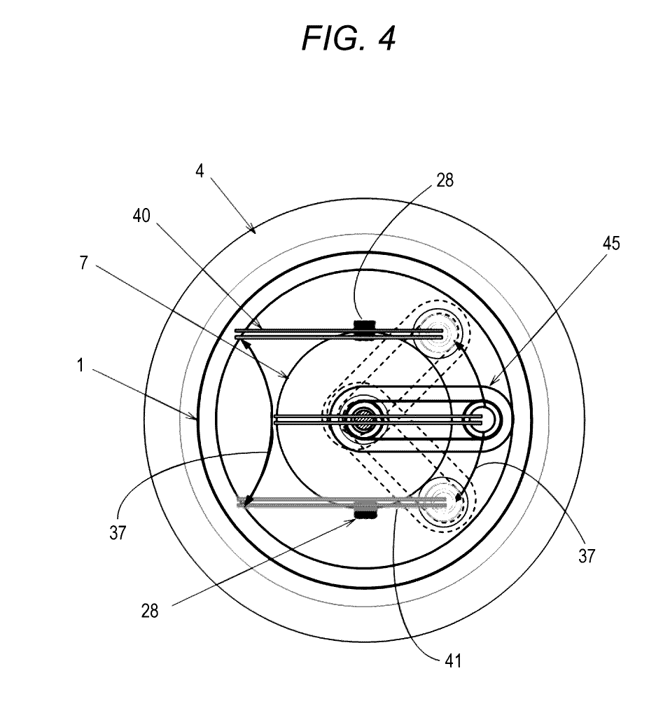

By the rotation driving unit 35 and the plasma electrode mechanism 58 configured as described above, the electrode 40 performs operation as illustrated in FIG. 4.

That is, boat driving force generated by rotation of the boat rotation motor 46 is transmitted to the rotation shaft 49 via the gear head 34, and the driving belt 61, and the boat table 13 is rotated in a state of loading the boat 5 holding the wafers 7 and dummy wafers 30 in multiple stages.

In addition, driving force of the electrode swing arm generated by rotation of the electrode swing motor 47 is transmitted to the electrode swing arm shaft 56 via the gear head 33 and the driving belt 60, and the electrode swing arm 45 is rotated that is coupled to electrode swing arm shaft 56. At this time, since the boat table base shaft 63 fixed to the seal cap 32 and the electrode support base shaft 57 are coupled together by the RF feeder belt 42, the electrode 40 and the electrode support 44 move horizontally without changing the direction, and move in the arc shape as a movement locus 37 of the electrode 40 as illustrated in FIG. 4.

With this configuration, in comparison with a method in which the electrode support 44 is simply made to be a rotation shaft, that is, the rotation shaft for moving the electrode 40 is made to be only one shaft, and the electrode 40 is swung in a fan shape, it becomes possible to move the electrode 40 in which plasma is generated in the entire surface of the wafers 7, and it becomes possible to uniformly modify a predetermined film formed on the surface of the wafers 7. That is, it becomes possible to solve a problem that, when the rotation shaft for moving the electrode 40 is provided to a position near the wall surface of the reaction tube 1 rather than a position coaxial to the rotation shaft 49, and the electrode 40 is made to be structure for operating in a fan shape to be operated, apart near the rotation shaft is modified a lot compared to the other part, and uniformity cannot be obtained in the surface of the wafers 7.

Further, by configuring the electrode swing arm shaft 56 to be coaxial to the boat rotation shaft 49, and coupling the electrode swing arm shaft 56 and the electrode support 44 together by the RF feeder belt 42 to form a link mechanism, it becomes possible to move the electrode 40 uniformly on the surface of the wafers 7, and it becomes possible to simplify the structure of the plasma electrode mechanism for obtaining the above-described effect.

(Exhaust Unit)

The reaction tube 1 is provided with the exhaust pipe 231 for exhausting an atmosphere in the processing chamber 201. The exhaust pipe 231 is connected to a vacuum pump 246 as a vacuum exhaust apparatus via a pressure sensor 245 as a pressure detector (pressure detecting unit) for detecting pressure in the processing chamber 201 and an auto pressure controller (APC) valve 244 as an exhaust valve (pressure adjusting unit). The APC valve 244 is a valve configured to be able to perform vacuum exhaust and vacuum exhaust stop in the processing chamber 201 by opening and closing the valve in a state of operating the vacuum pump 246, and further, to be able to adjust the pressure in the processing chamber 201 by regulating the degree of valve opening based on pressure information detected by the pressure sensor 245 in a state of operating the vacuum pump 246. An exhaust system is configured mainly by the exhaust pipe 231, the APC valve 244, and the pressure sensor 245. The vacuum pump 246 can be considered to be included in the exhaust system. The exhaust pipe 231, not limited to the case of being provided to the reaction tube 1, can be provided to the manifold 31, same as the nozzles 249a, 249b.

(Peripheral Apparatus)

Below the manifold 31, the seal cap 32 is provided as a furnace port lid capable of air tight closure of the lower end opening of the manifold 31. The seal cap 32 is configured to be in contact with the lower end of the manifold 31 from the vertical direction lower side. The seal cap 32 is made of metal such as SUS, and is formed in a disk shape. On the upper surface of the seal cap 32, an O ring 220b is provided as a seal member being in contact with the lower end of the manifold 31.

In the opposite side to the processing chamber 201 of the seal cap 32, a rotation mechanism 267 is installed for rotating the boat 5. The rotation shaft 49 of the rotation mechanism 267 is connected to the boat 5 by penetrating the seal cap 32. The rotation mechanism 267 is configured to rotate the wafers 7 by rotating the boat 5. The seal cap 32 is configured to be elevated in the vertical direction by a boat elevator 115 as an elevation mechanism vertically installed outside the reaction tube 1. The boat elevator 115 is configured to be able to carry the boat 5 in and out to the inside and outside of the processing chamber 201 by elevating the seal cap 32.

The boat elevator 115 is configured as a carrier apparatus (carrier mechanism) for carrying the boat 5, that is, wafers 7 to the inside and outside of the processing chamber 201. Below the manifold 31, a shutter 219s is provided as a furnace port lid capable of air tight closure of the lower end opening of the manifold 31 while lowering the seal cap 32 by the boat elevator 115. The shutter 219s is configured by metal such as SUS, and is formed in a disk shape. On the upper surface of the shutter 219s, an O ring 220c is provided as a seal member being in contact with the lower end of the manifold 31. Opening/closing operation (such as elevating operation and rotating operation) of the shutter 219s is controlled by a shutter opening/closing mechanism 115s.

In the reaction tube 1, a temperature sensor 263 is installed as a temperature detector. By adjusting an amount of energization to the heater 4 based on temperature information detected by the temperature sensor 263, temperature distribution in the processing chamber 201 becomes a desired temperature distribution. The temperature sensor 263 is configured in an L shape similarly to the nozzles 27, 29, and is provided along the inner wall of the reaction tube 1.

(Control Apparatus)

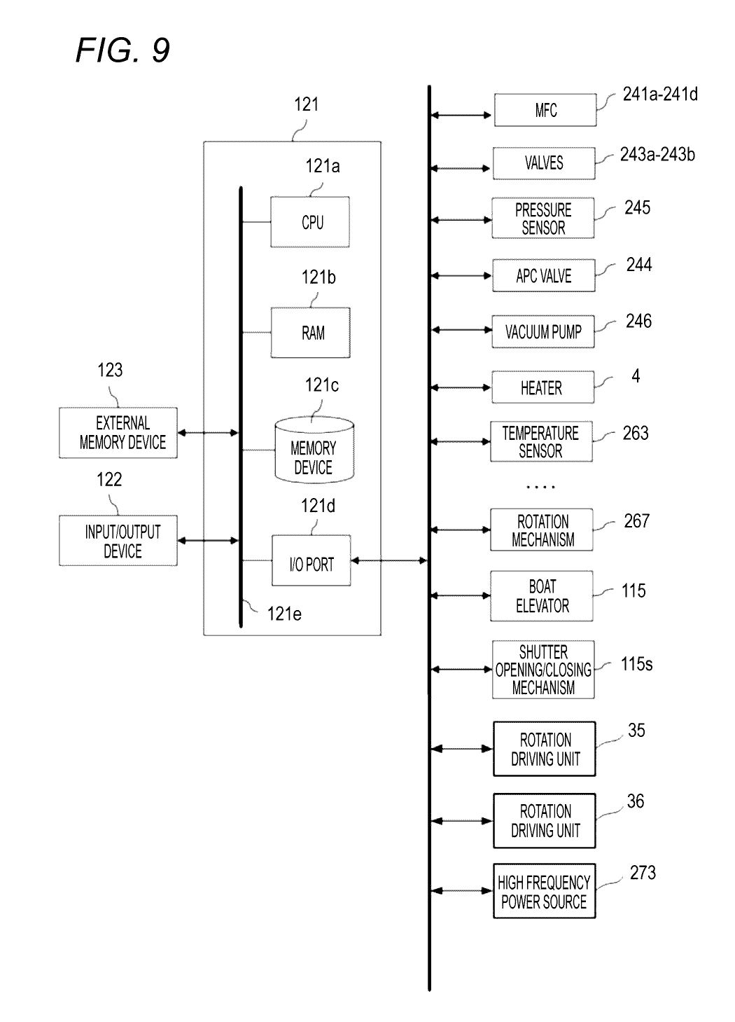

As illustrated in FIG. 9, a controller 121 being a control unit (control apparatus) is configured as a computer including a CPU (Central Processing Unit) 121a, a random access memory (RAM) 121b, a memory device 121c, and an I/O port 121d. The RAM 121b, the memory device 121c, and the I/O port 121d are configured to be capable of exchanging data with the CPU 121a via an internal bus 121e. The controller 121 is connected to an input/output device 122 configured as, for example, a touch panel.

The memory device 121c is configured by, for example, a flash memory, or a hard disk drive (HDD). The memory device 121c readably stores a control program for controlling operation of the substrate processing apparatus, a process recipe in which procedures and conditions of the film-forming processing described later are described, and the like. The process recipe functions as a program, in which the procedures in various types of processing (film-forming processing) described later are combined to be executed by the controller 121 to obtain a certain result. Hereinafter, the process recipe, the control program, and the like are also collectively referred to as, simply, a program. In addition, the process recipe is also referred to as, simply, a recipe. In the present specification, when using the term program, it may include the recipe alone, the control program alone, or both. The RAM 121b is configured as a memory area (work area) in which the program, data, and the like read by the CPU 121a are temporarily stored.

The I/O port 121d is connected to the above-described MFCs 241a-241d, valves 243a-243d, pressure sensor 245, APC valve 244, vacuum pump 246, temperature sensor 263, heater 4, rotation mechanism 267, boat elevator 115, shutter opening/closing mechanism 115s, rotation driving unit 35, matching device 36, oscillator (high frequency power source) 39, and the like.

The CPU 121a is configured to read the control program from the memory device 121c to execute, and to read the recipe from the memory device 121c depending on input of an operation command from the input/output device 122, and the like. The CPU 121a is configured to control: control of the rotation driving unit 35; power supply to the matching device 36; flow rate adjusting operation of various gases by the MFCs 241a-241d; on-off operation of the valves 243a-243d; on-off operation of the APC valve 244 and pressure adjusting operation by the APC valve 244 based on the pressure sensor 245; start and stop of the vacuum pump 246; temperature adjusting operation of the heater 4 based on the temperature sensor 263; forward and backward rotation, rotation angle, and rotation rate regulating operation of the boat 5 by the rotation mechanism 267; elevating operation of the boat 5 by the boat elevator 115; opening/closing operation of the shutter 219s by the shutter opening/closing mechanism 115s; impedance adjusting operation by the matching device 36; power supply to the oscillator 39; and the like, according to the content of the recipe read.

The controller 121 can be configured by installing the above-described program stored in an external memory device (for example, magnetic tape, magnetic disk such as flexible disk and hard disk, optical disk such as CD and DVD, magneto-optical disk such as MO, semiconductor memory such as USB memory and memory card) 123 to the computer. The memory device 121c and the external memory device 123 are configured as computer readable recording media. Hereinafter, these are also collectively referred to as, simply, recording media. When using the term recording media in the present specification, it may include the memory device 121c alone, the external memory device 123 alone, or both. Incidentally, the program can be provided to the computer by using communication means such as the Internet and a dedicated line without using the external memory device 123.

### (2) Substrate Processing

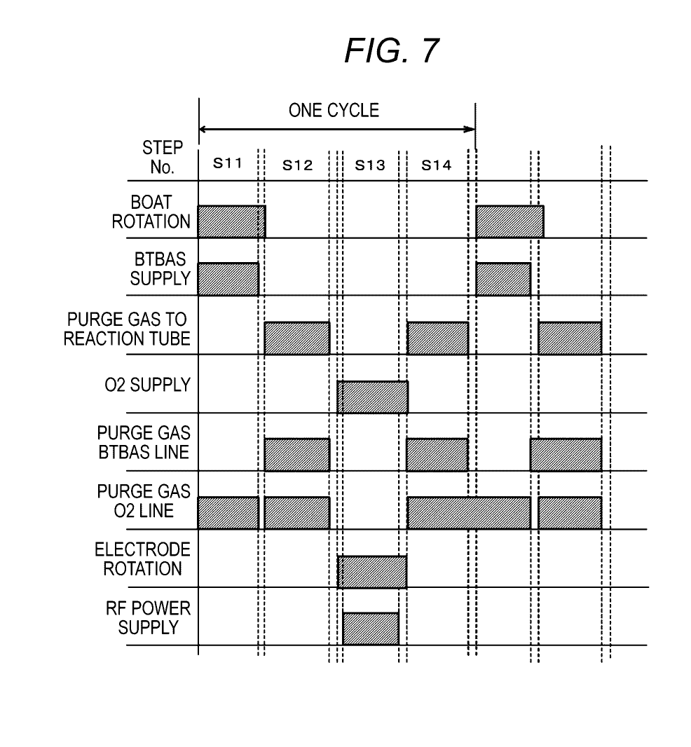

Using the above-described substrate processing apparatus, as one process of a manufacturing process of a semiconductor device, a process example is described of forming a film on the substrate with reference to FIG. 6 and FIG. 7. In the following description, operation of each part configuring the substrate processing apparatus is controlled by the controller 121.

In substrate processing (film-forming processing) illustrated in FIG. 6, a silicon oxide film (SiO film) is formed as a film containing Si and O on the wafers 7 by performing a first step and a second step a predetermined number of times (one or more times) non-simultaneously, that is, without synchronizing, the first step supplying the BTBAS gas as a source to the wafers 7 in the processing chamber 201, the second step supplying the O₂ gas in which plasma is excited as a reactant while moving the electrode to the wafers 7 in the processing chamber 201.

In the present specification, a sequence of the film-forming processing illustrated in FIG. 6, for convenience, may be represented as follows. In the description of following modification and other embodiment, the same notation is used.

(BTBAS→O₂*)×n [symbol] SiO

In the present specification, when using the term “a wafer,” it may mean “the wafer itself,” or “a laminated body (aggregated body) of the wafer and a predetermined layer, film, or the like formed on the surface of the wafer,” that is, it may be referred to as the wafer including the predetermined layer, film, or the like formed on the surface of the wafer. In addition, in the present specification, when using the term “a surface of the wafer,” it may mean the surface of the wafer itself (exposed surface),” or “a surface of a predetermined layer, film, or the like formed on the wafer, that is, an outermost surface of the wafer as the laminated body.”

Therefore, in the present specification, when described as “supply the predetermined gas to the wafer,” it may mean that “directly supply the predetermined gas to the surface of the wafer itself (exposed surface),” or it may mean that “supply the predetermined gas to the layer, film, or the like formed on the wafer, that is, to the outermost surface of the wafer as the laminated body.” In addition, in the present specification, when described as “form the predetermined layer (or film) on the wafer,” it may mean that “directly form the predetermined layer (or film) on the surface of the wafer itself (exposed surface),” or it may mean that “form the predetermined layer (or film) on the layer, film or the like formed on the wafer, that is, on the outermost surface of the wafer as the laminated body.”

In addition, in the present specification, even when using the term “substrate,” it is the same as of when using the term “wafer.”

(Loading Step: S1)

When the wafers 7 are charged to the boat 5 (wafer charge), the shutter 219s is moved by the shutter opening/closing mechanism 115s, and the lower end opening of the manifold 31 is opened (shutter open). After that, as illustrated in FIG. 1, the boat 5 supporting the wafers 7 is lifted by the boat elevator 115 to be loaded into the processing chamber 201 (boat load). In this state, the seal cap 32 becomes a state of sealing the lower end of the manifold 31 via the O ring 220b.

(Pressure and Temperature Adjusting Steps: S2, S3)

The processing chamber 201, that is, the space in which the wafers 7 exist is vacuum-exhausted (decompressed) by the vacuum pump 246 to achieve a desired pressure (degree of vacuum). At this time, the pressure in the processing chamber 201 is measured by the pressure sensor 245, and based on the pressure information measured, feedback control is performed of the APC valve 244. The vacuum pump 246 always maintains a state of being operated at least until the modification processing described later is completed.

In addition, heating is performed by the heater 4 so that temperature of the wafers 7 in the processing chamber 201 becomes a desired temperature. At this time, feedback control is performed of the amount of energization to the heater 4 based on the temperature information detected by the temperature sensor 263 so that temperature distribution in the processing chamber 201 becomes a desired temperature distribution. The heating by the heater 4 in the processing chamber 201 is continuously performed at least until the purge processing described later is completed. However, when the film-forming processing and purge processing described later is performed under the temperature condition equal to or less than the room temperature, the heating by the heater 4 in the processing chamber 201 does not have to be performed. Incidentally, when only the processing under such temperature is performed, the heater 4 becomes unnecessary, and the heater 4 does not have to be installed in the substrate processing apparatus. In this case, the configuration of the substrate processing apparatus can be simplified.

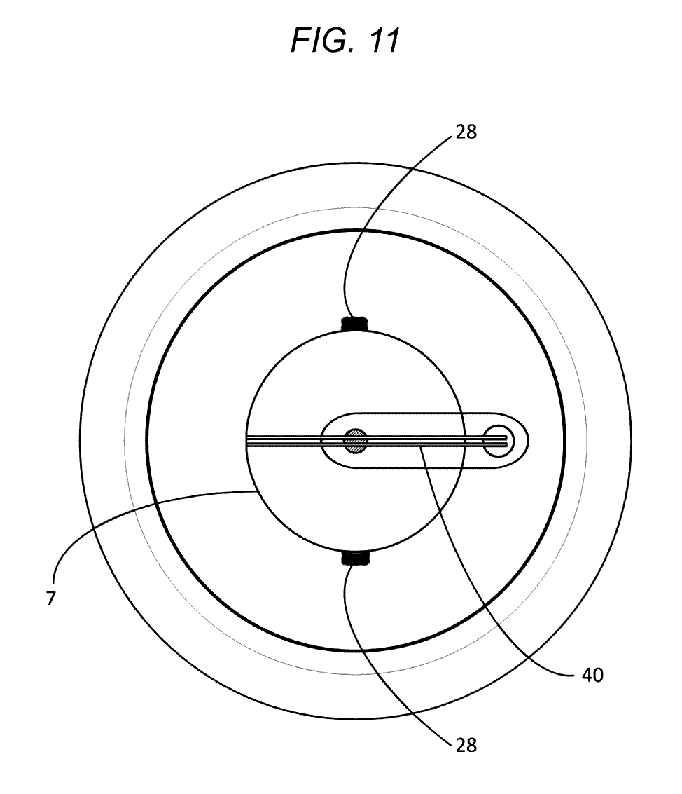

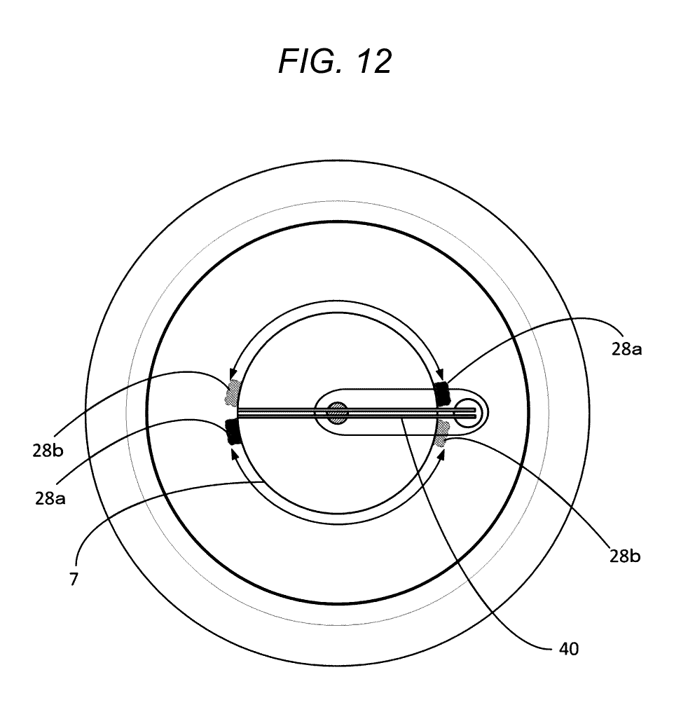

Subsequently, rotation of the boat 5 and wafers 7 is started by the rotation mechanism 267. The rotation of the boat 5 and wafers 7 by the rotation mechanism 267 is continuously performed at least until BTBAS supply described later is completed. While BTBAS being the source gas is supplied, the electrode 40, as illustrated in FIG. 11, is stopped above the center of the wafers 7. However, the rotation of the boat 5 and wafers 7, as illustrated in FIG. 12, repeats reciprocating motion (forward and backward rotation) in a range (about 150 degrees) in which boat supports 28a, 28b are not in contact with the electrode 40 stopped. That is, when the boat 5 is rotated to the right from the state illustrated in FIG. 11, the boat support 28 is rotated to the position of the boat support 28a illustrated in FIG. 12, and when the boat 5 is rotated to the left, the boat support 28 is rotated to the position of the boat support 28b illustrated in FIG. 12.

(Film-Forming Steps: S11, S12, S13, S14)

After that, film-forming steps are performed by sequentially executing steps S11, S12, S13, and S14.

[Source Supply Steps: S11, S12]

In step S11, the BTBAS gas is supplied to the wafers 7 in the processing chamber 201. Incidentally, the step S11 can be referred to as source gas supply step S11.

The valve 243a is opened, and the BTBAS gas flows into the gas supply pipe 232a. The BTBAS gas, after the flow rate adjustment is performed by the MFC 241a, is supplied into the processing chamber 201 via the nozzle 27, and exhausted from the exhaust pipe 231. At this time, the BTBAS gas is supplied to the wafers 7. At the same time, the valve 243c is opened, and N₂ gas flows into the gas supply pipe 232c. The N₂ gas, after the flow rate adjustment is performed by the MFC 241c, is supplied into the processing chamber 201 with the BTBAS gas, and exhausted from the exhaust pipe 231.

In addition, to prevent penetration of the BTBAS gas into the nozzle 29, the valve 243d is opened, and the N₂ gas flows into the gas supply pipe 232d. The N₂ gas is supplied into the processing chamber 201 via the gas supply pipe 232b and the nozzle 29, and exhausted from the exhaust pipe 231.

A supply flow rate of the BTBAS gas controlled by the MFC 241a is, for example, a flow rate in a range of 1-2000 sccm, preferably 10-1000 sccm. Each of supply flow rates of the N₂ gas respectively controlled by the MFCs 241c, 241d is, for example, a flow rate in a range of 100-10000 sccm. The pressure in the processing chamber 201 is, for example, pressure in a range of 1-2666 Pa, preferably, 67-1333 Pa. Time for supplying the BTBAS gas to the wafers 7, that is, gas supply time (exposure time) is, for example, time in a range of 1-100 s, preferably, 1-50 s.

A temperature of the heater 4 is set to a temperature that takes the temperature of the wafers 7 to a temperature (first temperature), for example, in a range of 0° C. or more and 150° C. or less, preferably, a room temperature (25° C.) or more and 100° C. or less, more preferably, 40° C. or more and 90° C. or less. The BTBAS gas is easily adsorbed to the wafers 7 and the like, and is highly reactive gas. Therefore, even in a low temperature of, for example, about the room temperature, the BTBAS gas can be chemisorbed onto the wafers 7, and a practical deposition rate can be obtained. As in the present embodiment, by setting the temperature of the wafers 7 to 150° C. or less, further, 100° C. or less, further, 90° C. or less, the amount of heat applied to the wafers 7 can be reduced, and control can be satisfactorily performed of a thermal history received by the wafers 7. In addition, when the temperature is 0° C. or more, BTBAS can be sufficiently adsorbed onto the wafers 7, and a sufficient deposition rate can be obtained. Therefore, it is preferable that the temperature of the wafers 7 is a temperature in a range of 0° C. or more and 150° C. or less, preferably, the room temperature or more and 100° C. or less, more preferably, 40° C. or more and 90° C. or less.

At this time, the electrode 40, as illustrated in FIG. 11, is stopped above the center of the wafers 7. It can be said that the electrode 40 vertically crosses a line connecting between two boat supports 28, and is stopped at a position having the same distance from the two boat supports 28. In addition, when the source gas is supplied, the boat 5 and wafers 7, as illustrated in FIG. 12, rotate only the boat 5 and repeat the reciprocating motion (forward and backward rotation) in a range (about 150 degrees) in which the boat supports 28a, 28b are not in contact with the electrode 40 stopped. That is, when the boat 5 is rotated to the right from the state illustrated in FIG. 11, the boat support 28 is rotated to the position of the boat support 28a illustrated in FIG. 12, and when the boat 5 is rotated to the left, the boat support 28 is rotated to the position of the boat support 28b illustrated in FIG. 12.

By supplying the BTBAS gas to the wafers 7 under the above-described condition, a Si-containing layer is formed of thickness of, for example, about from less than one atomic layer to several-atom layer on the wafers 7 (base film on the surface). The Si-containing layer can be a Si layer, and can be an adsorption layer of BTBAS, and can include the both layers.

The Si layer is a general term including, other than a contiguous layer configured by Si, a non-contiguous layer, and a Si thin film configured by the contiguous and non-contiguous layers overlapped with each other. The contiguous layer configured by Si may be referred to as the Si thin film. The Si configuring the Si layer includes the one in which the bond with the amino group is not completely broken, and the one in which the bond with H is not completely broken.

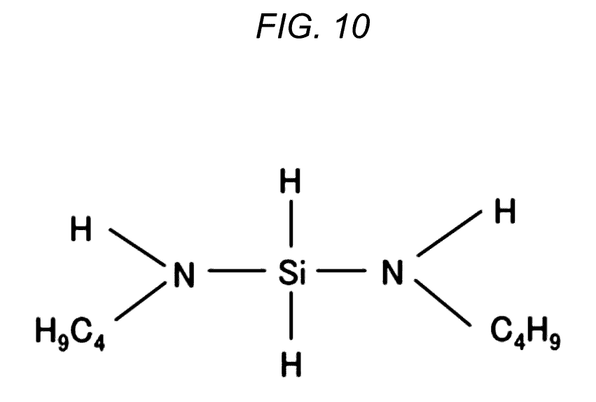

The adsorption layer of BTBAS includes, other than a contiguous adsorption layer configured by a BTBAS molecule, a non-contiguous adsorption layer. That is, the adsorption layer of BTBAS includes the adsorption layer of thickness of equal to one molecular layer or less than one molecular layer configured by the BTBAS molecule. The BTBAS molecule configuring the adsorption layer of BTBAS includes not only the one of which chemical structural formula is illustrated in FIG. 10, but also the one in which a bond between Si and the amino group is partially broken, the one in which a bond between Si and H is partially broken, and the one in which a bond between N and C is partially broken. That is, the adsorption layer of BTBAS can be a physical adsorption layer of BTBAS, and can be a chemical adsorption layer of BTBAS, and can include the both layers.

Here, a layer of thickness of less than one atomic layer means an atomic layer non-contiguously formed, and a layer of thickness of one atomic layer means an atomic layer contiguously formed. A layer of thickness of less than one molecular layer means a molecular layer non-contiguously formed, and a layer of thickness of one molecular layer means a molecular layer contiguously formed. The Si-containing layer may include both of the Si layer and the adsorption layer of BTBAS. However, as described above, for the Si-containing layer, expressions of “one atomic layer,” “several-atom layer” are used.

Under a condition in which autolysis (pyrolysis) of BTBAS occurs, that is, under a condition in which pyrolysis reaction of BTBAS is generated, Si is deposited on the wafers 7 to form the Si layer. Under a condition in which autolysis (pyrolysis) of BTBAS does not occur, that is, under a condition in which pyrolysis reaction of BTBAS is not generated, BTBAS is adsorbed on the wafers 7 to form the adsorption layer of BTBAS. However, in the present embodiment, since the temperature of the wafers 7 is set to a low temperature (first temperature) of, for example, equal to or less than 150° C., the pyrolysis of BTBAS hardly occurs. As a result, on the wafers 7, the adsorption layer of BTBAS is more easily formed than the Si layer.

When the thickness of the Si-containing layer formed on the wafers 7 exceeds several-atom layer, an effect of the modification in the modification processing described later does not reach the entire of the Si-containing layer. In addition, the minimum value is less than one atomic layer of the thickness of the Si-containing layer that can be formed on the wafers 7. Therefore, it is preferable that the thickness of the Si-containing layer is about from less than one atomic layer to several-atom layer. By making the thickness of the Si-containing layer equal to or less than one atomic layer, that is, one atomic layer or less than one atomic layer, the effect can be relatively improved of modification in the modification processing described later, and time can be shortened that is required for modification reaction in the modification processing. Time can also be shortened that is required for forming the Si-containing layer in the film-forming processing. As a result, processing time for one cycle can be shortened, and processing time in total can also be shortened. That is, the deposition rate can also be increased. In addition, by making the thickness of the Si-containing layer equal to or less than one atomic layer, controllability of film thickness uniformity can also be improved.

After forming the Si-containing layer, the valve 243a is closed, and supply of the BTBAS gas into the processing chamber 201 is stopped. At this time, the APC valve 244 is kept open, and the processing chamber 201 is vacuum-exhausted by the vacuum pump 246 to exclude from the inside of the processing chamber 201 the BTBAS gas unreacted or after contributing formation of the Si-containing layer, reaction byproduct, and the like remaining in the processing chamber 201 (S12). In addition, the valves 243c, 243d are kept open to maintain the supply of the N₂ gas into the processing chamber 201. The N₂ gas acts as purge gas, so that the effect can be improved of excluding from the inside of the processing chamber 201 the BTBAS gas unreacted or after contributing the formation of the Si-containing layer, and the like remaining in the processing chamber 201. Incidentally, the step S12 can be referred to as source gas purge step S12.

At this time, the gas remaining in the processing chamber 201 does not have to be completely excluded, and the inside of the processing chamber 201 does not have to be completely purged. When the amount of the gas remaining in the processing chamber 201 is very small, an adverse effect does not occur in the purge processing to be subsequently performed. At this time, the flow rate of the N₂ gas to be supplied into the processing chamber 201 does not have to be a large flow rate, and, for example, by supplying about the same amount as the volume of the reaction tube 1 (processing chamber 201), a purge can be performed of an extent in which the adverse effect does not occur in the purge processing. In this way, the inside of the processing chamber 201 is not completely purged, so that purge time can be shortened, and throughput can be improved. In addition, it is also possible to suppress the consumption of the N₂ gas to a minimum requirement.

As the source, other than the BTBAS gas, the gases can be suitably applied, such as tetrakis(dimethylamino)silane (Si[N(CH₃)₂]₄, abbreviation: 4DMAS) gas, tris(dimethylamino)silane (Si[N(CH₃)₂]₃H, abbreviation: 3DMAS) gas, bis(dimethylamino)silane (Si[N(CH₃)₂]₂H₂, abbreviation: BDMAS) gas, bis(diethylamino)silane (Si[N(C₂H₅)₂]₂H₂, abbreviation: BDEAS) gas. That is, as the source gas, the gases can be suitably applied, such as various aminosilane source gases, such as dimetylaminosilane (DMAS) gas, diethylaminosilane (DEAS) gas, dipropylaminosilane (DPAS) gas, diisopropylaminosilane (DIPAS) gas, butylaminosilane (BAS) gas, hexamethyldisilazane (HMDS) gas, and inorganic-based halosilane source gas, such as monochlorosilane (SiH₃Cl, abbreviation: MCS) gas, dichlorosilane (SiH₂Cl₂, abbreviation: DCS) gas, trichlorosilane (SiHCl₃, abbreviation: TCS) gas, tetrachlorosilane, that is, silicontetrachloride (SiCl₄, abbreviation: STC) gas, hexachlorodisilane (Si₂Cl₆, abbreviation: HCDS) gas, octachlorotrisilane (Si₃Cl₈, abbreviation: OCTS) gas, and inorganic-based silane source gas not containing a halogen group, such as monosilane (SiH₄, abbreviation: MS) gas, disilane (Si₂H₆, abbreviation: DS) gas, trisilane (Si₃H₈, abbreviation: TS) gas.

As the inert gas, other than the N₂ gas, rare gases can be used, such as Ar gas, He gas, Ne gas, Xe gas.

[Reactant Supply Steps: S13, S14]

After completing the film-forming processing, the O₂ gas as reaction gas in which plasma is excited is supplied to the wafers 7 in the processing chamber 201 (S13). At this time, rotation of the boat 5 is stopped. Incidentally, the step S13 can be referred to as reaction gas supply step S13.

In this step, on-off control of the valves 243b-243d is performed in the same procedure as the on-off control of the valves 243a, 243c, 243d in steps S11, S12. The O₂ gas, after the flow rate adjustment is performed by the MFC 241b, is supplied into the processing chamber 201 via the nozzle 249b. At this time, high frequency power is supplied to the electrode 40. The O₂ gas supplied into the processing chamber 201, in which plasma is excited immediately above each of the wafers 7, is supplied to the wafers 7 as active species (O₂*), and exhausted from the exhaust pipe 231. In this way, the O₂ gas activated (excited) by the plasma is uniformly supplied in accordance with movement of the electrode 40, to the wafers 7.

A supply flow rate of the O₂ gas controlled by the MFC 241b is, for example, a flow rate in a range of 100-10000 sccm. High frequency power applied to the electrode 40 is, for example, power in a range of 50-1000 W. The pressure in the processing chamber 201 is, for example, pressure in a range of 1-100 Pa. By using plasma, even when the pressure in the processing chamber 201 is in such relatively low pressure zone, the O₂ gas can be activated. Time for supplying the active species obtained by plasma excitation of the O₂ gas to the wafers 7, that is, gas supply time (exposure time) is, for example, time in a range of 1-100 s, preferably, 1-50 s. The other processing condition is the same as the processing condition of the above-described steps S11, S12.

Simultaneously with supply of the O₂ gas, the electrode swing arm 45 is driven to drive the electrode 40 in an arc shape. The electrode 40 of which driving range is the range illustrated in the electrode movement locus 37, turns before being in contact with the boat support 28 and moves in the opposite direction. After moving in the opposite direction, similarly, the electrode 40 turns before being in contact with the boat support 28 and reciprocates.

Simultaneously with driving of the electrode 40, high frequency power output from the oscillator 39 is supplied to the electrode 40 via the matching device 36, isolation transformer 38, RF feeder 43, RF feeder belt 42, electrode support base shaft 57, and electrode support 44, to generate oxygen plasma 41.

Ions and electrically neutral active species generated in the oxygen plasma 41, while moving the processing position according to the movement of the electrode 40 above the wafers 7, performs oxidation processing described later to the Si-containing layer formed on the surface of the wafers 7.

After supply of the high frequency power is stopped when the swing operation of the plasma electrode 40 is completed, introduction of oxygen is stopped. Incidentally, the supply of the high frequency power can be stopped before the swing operation of the plasma electrode 40 is completed.

By supplying the O₂ gas to the wafers 7 under the above-described condition, plasma oxidation is performed to the Si-containing layer formed on the wafers 7. At this time, by energy of the O₂ gas in which plasma is excited, the Si—N bond, and Si—H bond included in the Si-containing layer are broken. N, H of which bonds to Si are broken, and C bonding to N are separated from the Si-containing layer. Then, Si in the Si-containing layer including a dangling bond due to separation of N and the like, is bonded to O contained in the O₂ gas to form a Si—O bond. By progress of this reaction, the Si-containing layer is changed (modified) to a layer containing Si and O, that is, a silicon oxidation layer (SiO layer).

Incidentally, to modify the Si-containing layer to the SiO layer, it is necessary to supply the O₂ gas in which plasma is excited. This is because, even when the O₂ gas is supplied in an atmosphere of non-plasma, in the above-described temperature zone, energy is not enough for required amount for oxidizing the Si-containing layer, and it is difficult to sufficiently separate N and C from the Si-containing layer, and to sufficiently oxidize the Si-containing layer to increase the Si—O bond.

After changing the Si-containing layer to the SiO layer, the valve 243b is closed, and the supply of the O₂ gas is stopped. In addition, the supply of the high frequency power to the rod-shaped electrode 40 is stopped. Then, by the same processing procedure, processing condition as those of steps S11, S12, the O₂ gas and reaction byproduct remaining in the processing chamber 201 are excluded from the processing chamber 201 (S14). At this time, same as the step S12, the O₂ gas and the like remaining in the processing chamber 201 do not have to be completely excluded. Incidentally, the step S14 can be referred to as reaction gas purge step S14.

As the oxidant, that is, the O-containing gas in which plasma is excited, other than the O₂ gas, the gases can be used, such as nitrous oxide (N₂O) gas, nitric monoxide (NO) gas, nitrogen dioxide (NO₂) gas, ozone (O₃) gas, hydrogen peroxide (H₂O₂) gas, water vapor (H₂O gas), carbon monoxide (CO) gas, carbon dioxide (CO₂) gas.

As the inert gas, other than the N₂ gas, for example, various rare gases exemplified in steps S11, S12 can be used.

[Predetermined Number of Times Execution: S4]

When one cycle is to execute the above-described S11, S12, S13, S14 in this order non-simultaneously, that is, without synchronizing, by performing the cycle a predetermined number of times (n times), that is, one or more times, the SiO film can be formed of predetermined composition and predetermined thickness on the wafers 7. It is preferable to repeat the above-described cycle multiple times. That is, it is preferable that thickness of the SiO layer formed per one cycle is made smaller than a desired film thickness, and the above-described cycle is repeated multiple times until the film thickness of the SiO film to be formed by laminating the SiO layer becomes the desired film thickness.

(Atmospheric Pressure Return Steps: S5, S6)

When the above-described film-forming processing is completed, the valve 243b is closed, and the supply of the O₂ gas is stopped. In addition, the supply of the high frequency power between the rod-shaped electrodes 40 is stopped. Then, the valves 243c, 243d are opened, and the N₂ gas as the inert gas is supplied to the processing chamber 201 from each of the gas supply pipes 232c, 232d, and exhausted from the exhaust pipe 231. Thus, the inside of the processing chamber 201 is purged by the inert gas, and the O₂ gas and the like remaining in the processing chamber 201 are removed from the processing chamber 201 (inert gas purge). After that, the atmosphere in the processing chamber 201 is substituted by the inert gas (inert gas substitution), and the pressure in the processing chamber 201 is returned to the normal pressure (atmospheric pressure return).

(Unloading Step: S7)

After that, the seal cap 32 is lowered by the boat elevator 115 to open the lower end of the manifold 31, and the wafers 7 processed is unloaded to the outside of the reaction tube 1 from the lower end of the manifold 31 in a state of being supported by the boat 5 (boat unload). After the boat unload, the shutter 219s is moved, and the lower end opening of the manifold 31 is sealed by the shutter 219s via the O ring 220c (shutter close). The wafers 7 processed, after being unloaded to the outside of the reaction tube 1, are taken out from the boat 5 (wafer discharge). Incidentally, after the wafer discharge, an empty boat 5 can be loaded into the processing chamber 201.

### (3) Effects of the Present Embodiment

According to the present embodiment, one or more effects described below are obtained.

(a) Since film-forming is performed by generating plasma immediately above the substrates to be processed stacked in multiple stages, processing time is shortened, and productivity is improved.

(b) Since a thermal budget can be reduced by shortening the processing time, performance and quality of the semiconductor device can be improved.

(c) In the vertical type substrate processing apparatus in which the multiple substrates are stacked in the height direction, it is not possible to provide a mechanism for moving the electrode immediately above the substrates, so that it is necessary to insert the electrode from the outside of the boat. The present teaching, to achieve such a configuration, includes an electrode driving arm provided below the boat and of which support is disposed outside the outer diameter of the boat. Therefore, also in the vertical type substrate processing apparatus, it becomes possible to perform processing uniformly by plasma on each substrate surface, and uniformity of film quality and film thickness can be improved within the surface and between the surfaces.

(d) By single joint type link mechanism structure for moving the electrode in parallel, horizontal movement (translational operation) of the electrode can be achieved with the simplest structure.

(e) Since there is the boat support for the boat, when the electrode is inserted between the wafers, the boat cannot make one rotation as in the normal vertical type apparatus. Therefore, in the present embodiment, during the reaction gas supply, the electrode is operated after the rotation of the boat is stopped. Thus, the electrode and the boat support are not in contact with each other, so that it becomes possible to suppress generation of a particle.

In the present embodiment, it is described that the number of boat supports 28 is two; however, it can be three. In addition, in the configuration assumed in the present teaching, the electrode is in a state of being inserted between the wafers at all times, and extraction of the electrode depending on the steps is not performed. Therefore, in the present teaching, even during the source gas supply, the boat is controlled not to make one rotation.

### (4) Modified Example

The substrate processing of the present embodiment is not limited to the above-described aspect, and can be changed as in a modified example described below.

### First Modified Example

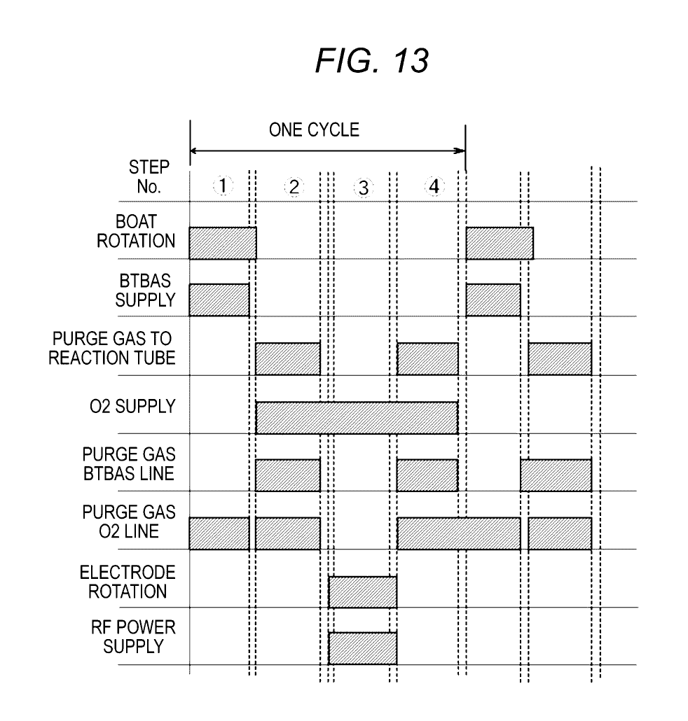

For example, as illustrated in FIG. 13, under the condition in which O₂ is not activated, the O₂ gas can be supplied with the purge gas in the source gas purge step S12 and the reaction gas purge step S14. By supplying O₂ in this way, it becomes possible to improve purge efficiency of the source gas and the reactant, and it becomes possible to shorten time required for the film-forming processing.

### Second Embodiment

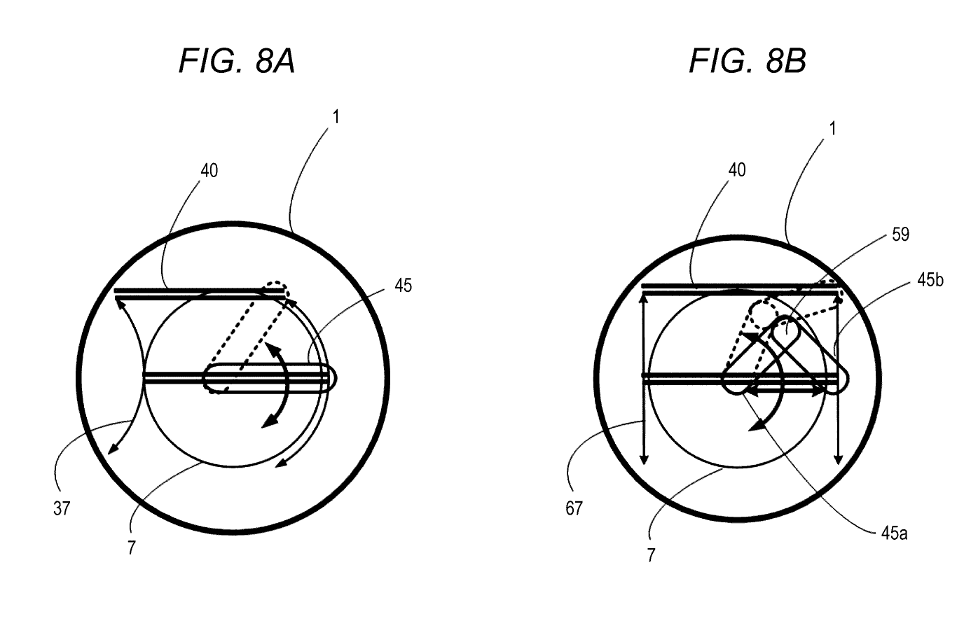

A second embodiment, as illustrated in FIG. 8B, is different from the first embodiment in that the electrode swing arm. 45 includes an arm joint unit 59 as a third electrode driving shaft between the electrode swing arm shaft 56 and the electrode support base shaft 57, and includes electrode swing arms 45a, 45b divided by the arm joint unit 59. With this configuration, the electrode 40 provided to the electrode support 44 can be moved linearly as a locus 67. When the movement of the electrode 40 is configured in two axes (three axes, when including an axis of the boat rotation) in this way, the structure becomes complicated; however, the electrode 40 can make a simple linear motion (translation) of sliding in the longitudinal direction instead of curve movement, and the operating space of the electrode swing arm 45 can be reduced compared to the first embodiment illustrated in FIG. 8A, and the diameter of the reaction tube 1 can be reduced since the distance can be reduced between the wafers 7 and the reaction tube 1.

According to the first embodiment, the second embodiment described above, in the vertical type substrate processing apparatus configured to stack the multiple substrates in the longitudinal direction to perform heat treatment, it can be said that the plasma electrode 40 is immediately above each of the wafers 7. In addition, it can be said that the electrode 40 reciprocates between the boat supports 28 facing each other. Further, it can be said that the electrode 40 reciprocates above the wafer being in a state of vertically crossing the straight line connecting the boat supports 28 facing each other. In addition, it can be said that one end in the longitudinal direction of the electrode 40 reciprocates along the periphery of the wafers 7. In addition, it can be said that the electrode 40 is stopped above the center of the wafers 7 while the source gas is supplied. In addition, it can be said that the electrode 40 reciprocates in a range in which the electrode 40 is not in contact with the boat support 28. In addition, it can be said that electrode 40 reciprocates so that one end and the other end in the longitudinal direction of the electrode 40 draw the same arc (curve). In addition, it can be said that the boat 5 rotationally moves in a range in which the support 28 is not in contact with the electrode 40. In addition, it can be said that the boat 5 rotationally reciprocates in a range of the rotational movement angle of 150 degrees.

The embodiments have been specifically described above. However, the present teachings not limited to the above-described embodiments, and can be variously modified without departing from the scope of the teaching.

For example, in the above-described embodiments, the example has been described in which capacitively coupled plasma (CCP) is used to generate plasma. The present teaching is not limited thereto, and any one can be used of inductively coupled plasma (ICP), electron cyclotron resonance plasma (ECR plasma), helicon wave excited plasma (HWP), and surface wave plasma (SWP).

In addition, for example, in the above-described embodiments, the example has been described in which the reactant is supplied after the source is supplied. The present teaching is not limited to such aspect, and supply order of the source, reactant can be reversed. That is, the source can be supplied after the reactant is supplied. By changing the supply order, film quality and a composition ratio of the film to be formed can be changed.

In the above-described embodiments, the example has been described in which the SiO film is formed on the wafers 7. The present teaching is not limited to such aspect, and can be suitably applied in a case in which a Si-based oxide film is formed on the wafers 7, such as a silicon oxycarbide film (SiOC film), silicon oxycarbonitride film (SiOCN film), and silicon oxynitride film (SiON film).

In addition, the present teaching can also be suitably applied to a case in which a silicon nitride film (Si₃N₄ film, hereinafter referred to as a SiN film) is formed on the wafers 7 by using the above-described Si-containing gas as the source gas, and using a nitrogen (N)-containing gas (nitridation gas) such as NH₃ gas as the reaction gas.

For example, as the reaction gas, gases can be used, such as hydrogen nitride-based gas such as ammonia (NH₃) gas, diazene (N₂H₂) gas, hydrazine (N₂H₄) gas, N₃H₈ gas, and gas containing a compound thereof. In addition, as the reaction gas, gases can be used, such as ethylamine-based gas such as triethylamine ((C₂H₅)₃N, abbreviation: TEA) gas, diethylamine ((C₂H₅)₂NH, abbreviation: DEA) gas, monoethylamine (C₂H₅NH₂, abbreviation: MEA) gas, and methylamine-based gas such as trimethylamine ((CH₃)₃N, abbreviation: TMA) gas, dimethylamine ((CH₃)₂NH, abbreviation: DMA) gas, monomethylamine (CH₃NH₂, abbreviation: MMA) gas. In addition, as the reaction gas, the present teaching can be suitably applied also in a case in which the SiN film is formed on the wafer by the film-forming sequence described below by using organic hydrazine-based gas such as trimethylhydrazine ((CH₃)₂N₂(CH₃)H, abbreviation: TMH).

(HCDS→NH₃*)×n [symbol] SiN

In addition, the present teaching can be suitably applied also in a case in which an oxide film is formed on the wafers 7, such as a metal-based oxide film and metal-based nitride film containing metal element such as titanium (Ti), zirconium (Zr), hafnium (Hf), tantalum (Ta), niobium (Nb), aluminum (Al), molybdenum (Mo), tungsten (W). That is, the present teaching can be suitably applied also in a case in which a film is formed on the wafers 7, such as a TiO film, TiOC film, TiOCN film, TiON film, TiN film, ZrO film, ZrOC film, ZrOCN film, ZrON film, ZrN film, HfO film, HfOC film, HfOCN film, HfON film, HfN film, TaO film, TaOC film, TaOCN film, TaON film, TaN film, NbO film, NbOC film, NbOCN film, NbON film, NbN film, AlO film, AlOC film, AlOCN film, AlON film, AlN film, MoO film, MoOC film, MoOCN film, MoON film, MoN film, WO film, WOC film, WOCN film, WON film, WN film.

The present teaching can be suitably applied also in a case in which a film is formed on the wafers 7, such as titanium oxide film (TiO film), hafnium oxide film (HfO film), zirconium oxide film (ZrO film), aluminum oxide film (AlO film), aluminum nitride film (AlN film), by the film-forming sequence described below, by using, for example, as the source gas, tetrakis(dimethylamino)titanium (Ti[N(CH₃)₂]₄, abbreviation: TDMAT) gas, tetrakis(ethylmethylamino)hafnium (Hf[N(C₂H₅)(CH₃)]₄, abbreviation: TEMAH) gas, tetrakis(ethylmethylamino)zirconium (Zr[N(C₂H₅)(CH₃)]₄, abbreviation: TEMAZ) gas, trimethylaluminum (Al(CH₃)₃, abbreviation: TMA) gas, titanium tetrachloride (TiCl₄) gas, hafnium tetrachloride (HfCl₄) gas.

(TDMAT→O₂*)×n [symbol] TiO

(TEMAH→O₂*)×n [symbol] HfO

(TEMAZ→O₂*)×n [symbol] ZrO

(TMA→O₂*)×n [symbol] AlO

(TMA→NH₃*)×n [symbol] AlN

That is, the present teaching can be suitably applied in a case in which the inside of the processing chamber 201 is purged after the processing is performed for forming the semiconductor-based film and the metal-based film. The processing procedure, processing condition of the film-forming processing can be the same processing procedure, processing condition as the film-forming processing described in the above-described embodiments and modified example. In addition, the processing procedure, processing condition of the purge processing to be performed after performing the film-forming processing, can be the same processing procedure, processing condition as the purge processing described in the above-described embodiments and modified example. Also in these cases, the same effects as the above-described embodiments are obtained.

It is preferable that recipes (programs in which the processing procedure and processing condition, and the like are described) used for the film-forming processing are prepared individually depending on processing details (film type, composition ratio, film quality, film thickness, processing procedure, processing condition, and the like of the thin film to be formed), and stored in the memory device 121c via a telecommunication line and the external memory device 123. It is preferable that, when various types of processing are started, the CPU 121a appropriately selects an appropriate recipe depending on the processing details, from the recipes stored in the memory device 121c. In this way, it becomes possible to form generally and with good reproducibility the thin film of various film type, composition ratio, film quality, film thickness, by one substrate processing apparatus. In addition, a burden of an operator (burden of inputting the processing procedure, processing condition, and the like) can be reduced, and the various types of processing can be quickly started while avoiding erroneous operation.

The above-described recipe, not limited to a case of being newly prepared, can be prepared by, for example, modifying the existing recipe already installed in the substrate processing apparatus. When the recipe is modified, the recipe modified can be installed in the substrate processing apparatus via the telecommunication line and a recording medium in which the recipe is recorded. In addition, the existing recipe already installed in the substrate processing apparatus can be directly modified by operating the input/output device 122 included in the existing substrate processing apparatus.

What is claimed is:

1. A substrate processing apparatus comprising:
a substrate holder configured to hold a substrate;
a gas supply unit configured to supply gas of processing the substrate;
a plasma electrode device provided separately above a surface of the substrate, configured to generate plasma of activating the gas supplied from the gas supply unit; and
a rotation driving unit connected to the plasma electrode device, configured to horizontally move the plasma electrode device above the substrate.

2. The substrate processing apparatus according to claim 1, wherein
the rotation driving unit includes
a first electrode driving shaft connected to the plasma electrode device, configured to rotate the plasma electrode device, and
an electrode driving source configured to rotate the first electrode driving shaft.

3. The substrate processing apparatus according to claim 2, wherein
the substrate holder further includes a rotation shaft configured to rotate the substrate holder, and
the rotation shaft and the first electrode driving shaft are coaxially configured to each other.

4. The substrate processing apparatus according to claim 1, further comprising
a control unit, wherein
the control unit controls the substrate holder to stop rotation operation while the plasma electrode device is operated by the rotation driving unit.

5. The substrate processing apparatus according to claim 2, wherein
the plasma electrode device includes
an electrode driving arm contiguously provided to the first electrode driving shaft,
an electrode support of which lower end is connected to the electrode driving arm, and
an electrode provided on a side surface of the electrode support.

6. The substrate processing apparatus according to claim 2, wherein
the electrode driving arm has a second electrode driving shaft at a position different from a position of the first electrode driving shaft.

7. The substrate processing apparatus according to claim 6, wherein
the second electrode driving shaft is provided outside from a periphery of the substrate holder.

8. The substrate processing apparatus according to claim 1, wherein
a plasma electrode mechanism moves at a constant speed above the substrate surface.

9. The substrate processing apparatus according to claim 6, wherein
the electrode driving arm has a third electrode driving shaft between the first electrode driving shaft and the second electrode driving shaft.

10. A method of manufacturing a semiconductor device, comprising:
supplying gas of processing a substrate held by a substrate holder;
generating plasma from a plasma electrode mechanism provided separately above a surface of the substrate to activate the gas supplied from the gas supply unit; and
moving horizontally the plasma electrode mechanism by the rotation driving unit connected to the plasma electrode device.

11. The method according to claim 10, wherein
operation of the substrate holder is stopped while the plasma is generated.

12. The method according to claim 10, wherein
the plasma electrode mechanism moves at a constant speed above the substrate surface.

13. A non-transitory computer-readable recording medium configured to record a procedure including:
supplying gas of processing a substrate held by a substrate holder;
generating plasma from a plasma electrode mechanism provided separately above a surface of the substrate to activate the gas supplied from a gas supply unit; and
moving horizontally the plasma electrode mechanism by a rotation driving unit connected to a plasma electrode device.

14. The non-transitory computer-readable recording medium according to claim 13, wherein
the procedure includes stopping operation of the substrate holder while the plasma is generated.

15. The non-transitory computer-readable recording medium according to claim 13, wherein
the procedure includes moving the plasma electrode mechanism at a constant speed above the substrate surface.
